(19) United States
(12) Patent Application Publication
(10) Pub. No.: US 2007/0227659 A1
(43) Pub. Date: Oct. 4, 2007

(54) PLASMA ETCHING APPARATUS

(75) Inventor: Hachishiro Iizuka, Amagasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/694,038

(22) Filed: Mar. 30, 2007

Related U.S. Application Data
(60) Provisional application No. 60/791,223, filed on Apr. 12, 2006.

(30) Foreign Application Priority Data
Mar. 31, 2006 (JP) 2006-099656

(51) Int. Cl. H01L 21/306

(52) U.S. Cl. 156/345.33

(57) ABSTRACT

A plasma etching apparatus for plasma-etching on an object includes a chamber; a support; a gas supply unit; a plasma generating unit; and a gas exhaust unit. The gas supply unit includes a gas supply tube having a gas injection opening for injecting the gases toward the object held on the support, the gas injection opening having one or more first gas supply openings and a second gas supply opening. The gas supply unit supplies the second gas to a surface of the object by injecting first the first gas toward the object from said one or more first gas supply openings into the chamber whose pressure has been reduced by the gas exhaust unit, and then injecting the second gas toward the object from the second gas supply opening via a space whose pressure is increased by the first gas.

### FIELD OF THE INVENTION

The present invention relates to a plasma etching apparatus.

### BACKGROUND OF THE INVENTION

Recently, in the field of a high-resolution flat panel display device, represented by a liquid crystal display device, or a high-precision semiconductor device, much attention has been paid on an apparatus which makes it possible to perform a highly precise processing on a semiconductor film by using a High Density Plasma (HDP) source capable of realizing a state of a high electronic density, ranging from 10¹¹ to 10¹³ cm⁻³.

HDP etching is performed by supplying a carrier gas, such as Ar or Kr, and an etching gas, such as HBr or NF₃, into a vacuum vessel (chamber), in which an object to be processed is disposed. Furthermore, generally, the HDP etching is performed in the state in which the inner pressure of the chamber is reduced to a range from 133.3 mPa to 13.3 Pa (from 1 mTorr to 100 mTorr).

The supply of gas into the chamber is performed by injecting a carrier gas and an etching gas, which have been mixed together in advance, into the chamber through the gas injection opening of a gas supply tube by using the gas supply tube that is inserted into an inside of the chamber from the outside of the chamber.

Patent Document 1 discloses an apparatus that is intended to be used to perform plasma Chemical Vapor Deposition (CVD) film formation, in addition to the plasma etching on an object to be processed, by using a single apparatus. In the apparatus, a mixture of an etching gas or a film material gas with a carrier gas is injected downwards through the gas injection openings in a shower head disposed above an object to be processed, or is injected laterally and above the object, through a gas ring manifold disposed to surround the object to be processed, or through the gas injection openings of a gas supply nozzle disposed along the side wall of a vacuum vessel.
[Patent Document 1] Japanese Unexamined Patent Publication No. Hei 7-169703

The conventional apparatus disclosed in Patent Document 1 is not optimized for the performance of plasma etching on an object to be processed at low cost. Plasma etching must be performed at a chamber pressure that is lower than the pressure applied while performing plasma CVD. However, as the inner pressure of the chamber is reduced, gas to be supplied to the surface of an object to be processed is easily diffused in the chamber. As a result, when the inner pressure of the chamber is reduced to a range suitable for plasma etching, the straightness of the gas stream supplied from gas injection openings to an object to be processed is deteriorated. Therefore, in the conventional apparatus, it is not easy to reduce the amount of supplied gas for the surface treatment of an object to be processed.

### SUMMARY OF THE INVENTION

It is, therefore, an object of the present invention to provide a plasma etching apparatus that is capable of reducing the amount of supplied gas required for the surface treatment of an object to be processed.

In accordance with an embodiment of the present invention, there is provided a plasma etching apparatus for plasma-etching on an object to be processed, including: a chamber; a support disposed in the chamber to hold the object to be processed; a gas supply unit for supplying gases into the chamber; a plasma generating unit for generating a plasma of the gases supplied into the chamber; and a gas exhaust unit for pumping the inside of the chamber to reduce an inner pressure of the chamber; wherein the gas supply unit includes a gas supply tube having a gas injection opening for injecting the gases toward the object to be processed held on the support, the gas injection opening having one or more first gas supply openings for injecting a first gas and a second gas supply opening for injecting a second gas for processing the object to be processed; and wherein the gas supply unit supplies the second gas to a surface of the object to be processed by injecting first the first gas toward the object to be processed from said one or more first gas supply openings into the chamber whose pressure has been reduced by the gas exhaust unit, and then injecting the second gas toward the object to be processed from the second gas supply opening via a space whose pressure has been increased by the first gas.

In a plasma etching apparatus in accordance with the present invention, a gas supply unit is configured to inject a first gas into a chamber, the pressure in which has been reduced, from a first gas supply opening toward an object to be processed and to inject a second gas into a space, the pressure in which has been increased by injecting the first gas, from a second gas supply hole toward the object to be processed. Accordingly, even in a chamber where the inner pressure thereof is reduced to the range (for example, from 133.3 mPa to 13.33 Pa) required for plasma etching, the straightness of the stream of the second gas injected toward the object to be processed can be improved, so that the amount of gas supplied for the surface treatment of the object to be processed can be reduced.

It is preferable that the gas supply tube has a first tube portion and a second tube portion into which the gases are introduced from the first tube portion, wherein the first tube portion is arranged to extend into the chamber toward a space of the chamber above the object to be processed along a direction substantially parallel to a surface of the object to be processed while the second tube portion having gas injection opening at a tip thereof extends substantially vertically to the surface of the object to be processed.

In the specification, the term “substantially parallel” means that the angle between the surface of the object to be processed and the lengthwise axis of the first tube portion is less than 10 degrees, preferably less than 5 degrees. Furthermore, the term “substantially vertical” means that the angle between the surface of the object to be processed and the lengthwise axis of the second tube portion is within a range of 80 to 100 degrees, preferably within a range of 85 to 95 degrees. The gas supply tube should be introduced into the chamber so as not to interfere with a plasma generating unit.

In the setup of the apparatus, it is impossible to vertically introduce the gas supply tube from a position above the object to be processed toward the surface thereof. In particular, in the case in which the plasma generating unit has a planar antenna, represented by a radial line slot antenna, which will be described later, and is disposed on the upper outside of the chamber so as to face the object to be processed, the gas supply tube must be disposed to be kept away from the space above the apparatus in which the antenna is disposed. In this case, in order to direct the gas injection opening of the gas supply tube toward the object to be processed, it is preferable to use a supply pipe in which first and second tube portions are disposed as described above.

The length of the second tube portion ranges from about 5 mm to 150 mm; more preferably from about 20 mm to 90 mm; and most preferably from about 25 mm to 50 mm.

Since the flow of the gas is disturbed while the gas moves from the first tube portion to the second tube portion, the peak in the distribution of the flow velocity of the injected gas can be shifted away from the vicinity of the center of the gas injection opening. In this case, it is difficult to uniformly treat the object to be processed. However, by allowing the gas to flow in the second tube portion having the above length, the disturbance of the gas flow can be put out and the gas can be injected in a state in which the peak in the distribution of the flow velocity of the gas returns to the vicinity of the center of the gas injection opening.

If the length of the second tube portion is excessively short, the disturbance of the gas flow cannot be fully put out. On the other hand, if the second tube portion is excessively long, the gas is not sufficiently dispersed. The shape of the pipe portion at which the first tube portion and the second tube portion communicate with each other is not limited, but an L shape is preferred.

It is preferable that the gas injection opening has one first gas supply opening and the first gas supply opening has a ring shape surrounding a second gas supply opening. Alternatively, it is preferable that the gas injection opening has more than one first gas supply opening disposed around the second gas supply opening. This is because the straightness of the stream of the second gas supplied can be improved by increasing the pressure of the space through which the second gas passes in the chamber.

It is also preferable that the gas supply tube has a wall surface causing the first and the second gas injected through the first gas supply openings and the second gas supply opening to collide therewith, and changes flow directions of the first and the second gas by causing the first and second gases to collide with the wall surface, thereby injecting the first and the second gas toward the object to be processed.

In this case, as in the above-described first tube portion, it is preferred that the gas supply tube include a pipe disposed substantially parallel to the surface of the object to be processed. The gas ejected from the gas supply tube collides with the wall surface and the direction of the flow of the gas is changed to a direction substantially perpendicular to the surface of the object to be processed.

It is preferable that the gas supply unit includes a gas supply control mechanism controlling supply of the first and the second gas, the gas supply control mechanism starting to inject the second gas while the first gas is being injected. This is because the pressure in the space through which the second gas passes in the chamber can definitely be increased.

It is preferable that a distance between the gas injection opening and the support ranges from about 10 mm to 150 mm. This is because sufficient working space around the support for holding the object to be processed can be secured.

The second gas may be a gas for etching the object to be processed or the second gas may alternatively be a gas for cleaning the surface of the object to be processed not reacting with the surface of the object to be processed.

If the second gas is a gas for etching the object to be processed, the amount of supplied gas required for etching in a reduced pressure environment can be reduced. If the second gas is a gas which does not react with the surface of the object to be processed, deposits accumulated on the surface of the object to be processed during etching treatment can be easily blown and removed, and therefore the amount of gas to be supplied for the cleaning treatment of the corresponding surface can be reduced.

It is preferable that the plasma generating unit include a high-density plasma source capable of realizing a high electronic density, ranging from 10¹¹ to 10¹³ cm⁻³, such as Capacitively Coupled Plasma (CCP), Electronic Cyclotron Resonance (ECR) plasma, Helicon Wave Plasma (HWP), inductively coupled plasma, and microwave surface wave plasma. In particular, it is preferable that the plasma generating unit includes a radial line slot antenna (RLSA), serving as a SWP source, provided with an antenna body provided with an outer surface forming a surface for radiating a microwave and disposed outside the chamber to face the object to be processed held by the support; a wave retarding plate formed of a dielectric member and disposed to cover the outer surface; and a slot plate having a plurality of slots to cover the dielectric member.

The RLSA has a plurality of slots disposed to generate uniform microwaves, so that it can achieve high plasma density across a wide area immediately under the antenna. Therefore, a plasma etching apparatus that is capable of performing uniform plasma treatment in a short time in the manufacture of a semiconductor device using a semiconductor substrate having a large diameter or a large-sized liquid crystal display device can be provided.

### BRIEF DESCRIPTION OF THE DRAWINGS

The above and other objects and features of the present invention will become apparent from the following description of embodiments given in conjunction with the accompanying drawings, in which:

FIG. 1 is a conceptual view illustrating an example of a plasma etching apparatus in accordance with the present invention;

FIG. 2 is a view illustrating a gas supply tube 1 shown in FIG. 1;

FIG. 3A is a longitudinal cross sectional view of the gas supply tube 1 shown in FIG. 1;

FIG. 3B is a transversal cross sectional view of the area around the tip of the gas supply tube 1 shown in FIG. 1;

FIG. 3C is a view illustrating the injection patterns of first and second gases injected from the gas supply tube 1 shown in FIG. 1;

FIG. 4A is a view illustrating another example of a gas supply tube;

FIG. 4B is a view showing the gas supply tube of FIG. 4A when viewed from the direction of B;

FIG. 5A is a view illustrating another example of the gas supply tube;

FIG. 5B is a view showing the gas supply tube of FIG. 5A when viewed in direction B;

FIG. 6A is a view illustrating another example of the gas supply tube;

FIG. 6B is a view showing the gas supply tube of FIG. 6A viewed in direction B;

FIG. 7A is a view illustrating another example of the gas supply tube;

FIG. 7B is a view showing the gas supply tube of FIG. 7A viewed in direction B;

FIG. 8A is a view illustrating another example of the gas supply tube;

FIG. 8B is a view showing the gas supply tube of FIG. 8A viewed in direction B;

FIG. 9A is a view illustrating another example of the gas supply tube; and

FIG. 9B is a view showing the gas supply tube of FIG. 9A viewed in direction B.

### DETAILED DESCRIPTION OF THE EMBODIMENTS

Preferred embodiments of the present invention will be described with reference to the accompanying drawings below. In the following description, same elements are assigned with same reference numerals, and descriptions of some of them may be omitted.

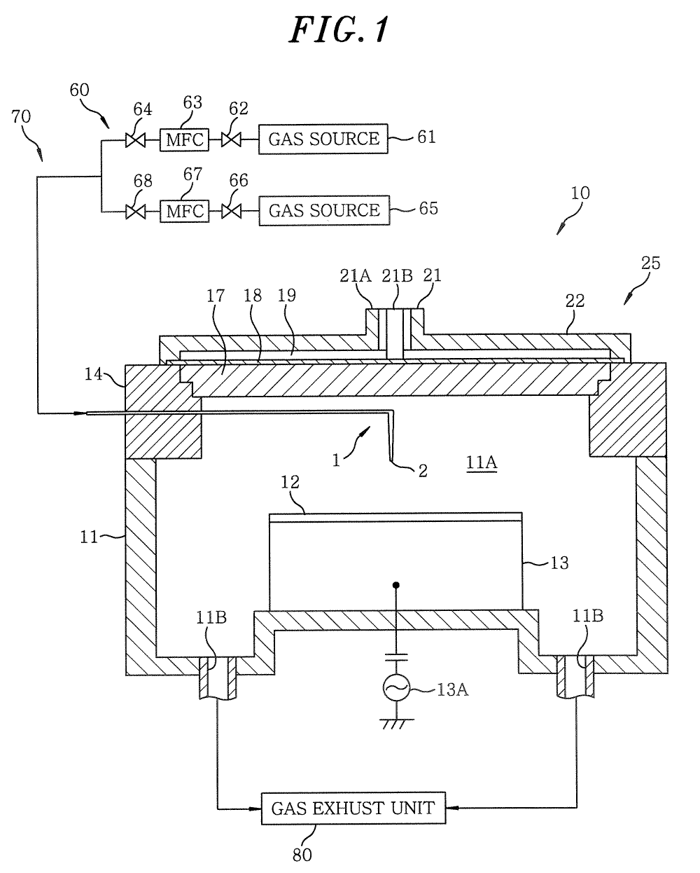

FIG. 1 is a conceptual view illustrating an example of a plasma etching apparatus of the present invention.

The plasma etching apparatus 10 includes a chamber 11, and a support 13 disposed in the chamber 11 and configured to hold an object to be processed 12. The support 13 holds the object to be processed 12 by using, for example, an electrostatic chuck. The object to be processed 12 is, for example, a semiconductor film formed on a substrate, a semiconductor device, or the like. It is preferable to have the chamber 11 made of, for example, austenite stainless steel containing aluminum and the support 13 made of, for example, Al₂O₃, AlN, or the like. A high frequency power source 13A for applying a high frequency voltage to the support 13 is connected to the support 13.

A gas exhaust port 11B is formed in the bottom wall of the chamber 11 to surround the support 13. A gas exhaust unit 80 including a vacuum pump is connected to the gas exhaust port 11B. By using the gas exhaust unit 80, the pressure of the space 11A in the chamber 11 can be reduced to a specific vacuum level, for example, ranging from 133.3 mPa to 13.33 Pa.

The portion of the ceiling of the chamber 11 that faces the object to be processed 12 is formed of a microwave transmitting window 17 that transmits microwaves therethrough. A sealing member 14 is inserted between the microwave transmitting window 17 and the side wall of the chamber 11. It is preferable that the microwave transmitting window 17 is made of, for example, quartz and the sealing member 14 is made of, for example, Al₂O₃ or AlN.

A Radial Line Slot Antenna (RLSA) 25 is disposed on an outer surface of the microwave transmitting window 17, wherein the outer surface is on the opposite side of the surface that faces the space 11A. The RLSA 25 includes a disc-shaped slot plate 18 disposed to be in contact with the microwave transparent window 17 and provided with a plurality of slots therein; a disc-shaped antenna body 22 configured to hold the slot plate 18; and a wave retarding plate 19 disposed between the slot plate 18 and the antenna 22. It is preferred that the wave retarding plate be made of a low loss dielectric material, for example, Al₂O₃, SiO₂, Si₃N₄ or the like. The antenna body 22 is disposed on the chamber 11 such that the outer surface thereof, which forms a surface for radiating microwaves, faces the object to be processed 12 held on the support 13.

The RLSA 25 is disposed on the chamber 11 via the sealing member 14. A Microwave is supplied from an external microwave source (not shown) to the RLSA 25 via an coaxial waveguide 21. The frequency of the microwave is set to, for example, 2.45 or 8.3 GHz. The outer waveguide 21A of the coaxial waveguide 21 is connected to the antenna body 22, and the central conductive body 21B thereof is connected to the slot plate 18 via an opening formed in the wave retarding plate 19. The microwave supplied to the coaxial waveguide 21 radially propagates between the antenna body 22 and the slot plate 18 while the wavelength of the microwave is reduced by the function of the wave retarding plate 19. It is preferred that two types of slot are formed in the slot plate 18, concentrically and perpendicularly to each other, in harmony with the radial propagation of the microwave. By employing the configuration described above, a uniform high-density plasma can be formed over a wide area immediately under the antenna because a circular polarized plane waves can be radiated from the slot plate 18 to the microwave transparent window 17 in a direction substantially perpendicular to the slot plate 18. The microwave is introduced into the chamber 11 via the microwave transparent window 17.

The microwave introduced into the chamber 11 via the microwave transparent window 17 ignite the plasma by exciting a plasma gas, such as Ar, Kr or the like, which is supplied into the chamber 11 form a gas supply unit 70 which will be described later. After igniting the plasma, an etching gas of NF₃, HBr, or the like is supplied into the chamber 11 from the gas supply unit 70 and a high frequency voltage is supplied from a high frequency power source 13A to the support 13 to pull the plasma to the surface of the object to be processed 12, so that reactive ion etching can be performed on the corresponding surface.

The plasma etching apparatus 10 is provided with the gas supply unit 70 for supplying a gas into the chamber 11. The gas supply unit 70 is provided with a gas supply tube 1 held by the sealing member 14 and introduced into the chamber 11 and a gas supply control mechanism 60 connected to the gas supply tube 1.

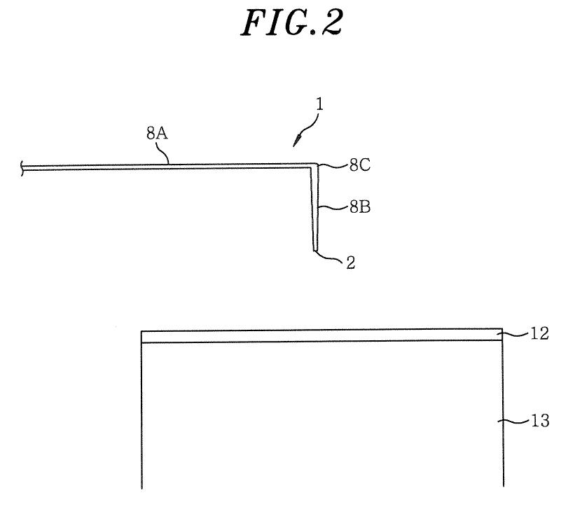

The gas supply tube 1, as shown in the drawing, is introduced into the chamber 11 in such a way that it is kept away from the antenna body 22. The gas supply tube 1, as shown in FIG. 2, includes a first tube portion 8A, a second tube portion 8B, and a bent tube portion 8C. The first tube portion 8A extends parallel to the outer surface of the antenna body 22, which forms a surface for radiating microwaves, toward a space within the chamber 11, which is formed above the object to be processed 12 with respect to the support 13. The first tube portion 8A also runs parallel to the surface of the object to be processed 12. The second tube portion 8B extends vertically from the surface of the object to be processed 12. A gas injection opening 2 is formed in the tip of the second tube portion 8B. The bent tube portion 8C located above the central portion of the object to be processed 12 is bent substantially at a right angle so that the first tube portion 8A and the second tube portion 8B can communicate with each other.

It is preferable to set the length of the second tube portion 8B to a value in a range, for example, from 5 to 150 mm, from 20 to 90 mm, or, occasionally, from 25 to 50 mm. As will be described later, this is because the uniform treatment of the object to be processed 12 can be facilitated.

It is preferable to dispose the gas supply tube 1 so that the gap between the gas injection opening 2 and the support 13 ranges from 10 to 150 mm, and the gas injection openings 2 opens to the central portion of the object to be processed 12 because it views the object to be processed 12 from above. A plurality of gas supply tubes may be provided. In this case, it is preferable that respective gas supply control mechanisms are connected independently to the gas supply tubes.

The gas supply tube 1 may be made of a material which is not easily corroded by an etching gas, for example, quartz, ceramic, a polyimide resin, a fluoric resin, and the like or may be made of a material the properties of which are not easily changed by plasma and a high temperature environment.

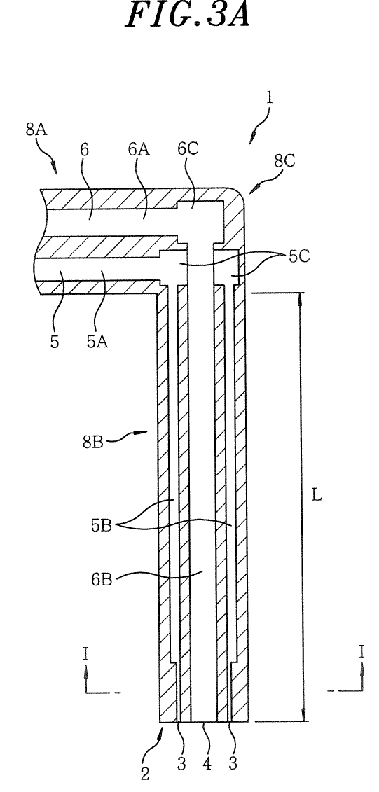

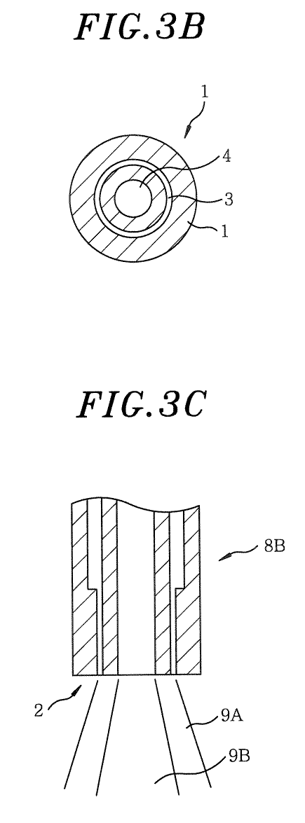

FIGS. 3A and 3B are a longitudinal cross sectional view and a transversal cross sectional view (taken along line I-I of FIG. 3A) in the vicinity of the tip of the gas supply tube 1, respectively, which illustrate the structure of the gas supply tube 1. First and second gas supply paths 5 and 6 are formed in the gas supply tube 1. The first and second gas supply paths 5 and 6 respectively includes a first section 5A and 6A formed in the first tube portion 8A and configured to extend substantially parallel to the surface of the object to be processed 12, a connection section 5C and 6C formed in the bent tube portion 8C, and a second section 5B and 6B formed in the second tube portion 8B and configured to extend substantially perpendicularly to the surface of the object to be processed 12. The ends of the first and second gas supply paths 5 and 6 respectively correspond to a first gas supply opening 3 and a second gas supply opening 4. The other ends (the other surfaces) thereof are connected to the gas supply control mechanism 60.

The gas injection opening 2 is configured such that the first gas supply opening 3, having a ring opening shape, is disposed in a ring shape to surround the second gas supply opening 4, having a circular opening shape, and such that the first and second supply openings 3 and 4 are opened toward the object to be processed 12. As shown in FIG. 3C, when the first and second gases are respectively injected through the first and second gas supply openings, the second gas is injected to the space 9A the pressure of which is increased by the first gas. In other words, the space 9A to which the first gas is injected includes the space 9B to which the second gas is injected.

The gas supply control mechanism 60 includes a source 61 of well-known carrier gas (including a plasma gas) that is represented by Ar or Kr, and does not react with the object to be processed, a source 65 of gas (etching gas) that includes a halogen element represented by NF₃, HBr and Cl₂ and is used to etch the surface of the object to be processed, mass flow controllers (MFC) 63 and 67 that are respectively connected to the gas sources 61 and 65, and opening/closing valves 62, 64, 66, and 68 that are disposed before and after the mass flow controllers 63 and 67. The gas supply control mechanism 60 controls the types and the flow rates of the gases injected through the first and second gas supply openings 3 and 4 of the gas supply tube 1. The gas supply control mechanism 60 may include a separate gas source.

It is preferable that the supply of the gas into the chamber is performed in such a way that the second gas is injected to the object to be processed 12 through the second gas supply opening 4 into the space, the pressure in which has been increased by the injection of the first gas, by supplying the second gas to the second supply path 6 in a state in which the first gas is injected toward the object to be processed 12 through the first gas supply opening 3 by introducing the first gas to the first gas supply path 5. By injecting the gases in this way, the straightness of the stream of the second gas supplied toward the object to be processed 12 can be improved even in a chamber the pressure in which has been reduced to the range, for example, from 133.3 mPa to 13.33 Pa, so that a sufficient amount of second gas for the surface treatment of the object to be processed 12 can be injected. Accordingly, the amount of gas supplied for the surface treatment of the object to be processed 12 can be reduced. In particular, even if the amount of second gas supplied to the second supply path 6 is reduced to a value within a range from 100 sccm to 2 slm, surface treatment can be satisfactorily performed. It is preferable to set the amount of first gas supplied to the first supply path 5 to a value within a range from 200 sccm to 5 slm.

It is preferable that the gas supply control mechanism 60 include, for example, a memory for storing a control program and a central processing unit for executing the program, so as to control the supply pattern of the gas as described above.

The length L of the second section 6B may be set to a value within a range, for example, from 5 mm to 150 mm, 20 mm to 90 mm, or, occasionally from 25 mm to 50 mm so as to correspond to the set length of the second tube portion SB. Since the gas passes through the connection section 6C when the gas moves from the first section 6A to the second section 6B, the flow of the gas is disturbed, the peak in the distribution of the flow velocity of the gas injected from the second gas supply opening 4 may be shifted away from the vicinity of the center of the gas supply port 4, that is, the vicinity of the center of the gas injection opening 2. However, the disturbance of the flow of the gas can be put out by allowing the gas to flow in the second section 6B, so that the gas can be injected with the peak in the distribution of the flow velocity of the gas located in the vicinity of the center of the gas injection openings. Accordingly, the uniform treatment of the object to be processed 12 can be facilitated.

As shown in FIG. 3A, it is preferable that the first supply path 5 be constructed such that the width of the opening of the first gas supply opening 3 is reduced by increasing the thickness of the pipe in the vicinity of the first gas supply opening 3. The reason for this is that a Venturi effect can be realized, so that the pressure in the space to which the first gas is injected can be easily increased even if the amount of supplied first gas is restricted. In the same manner, the width of the opening of the second gas supply opening 4 may be reduced.

A plurality of first gas supply openings 3 formed by branching the first supply path 5 may be disposed around the second gas supply opening 4, wherein the opening shapes of the first gas supply openings 3 are made circular. In this case, the second gas is injected into the space the pressure in which has been increased by injecting the first gas.

Although the first and second gases injected respectively through the first gas supply opening 3 and the second gas supply opening 4 can be appropriately selected depending on the purpose of the surface treatment of the object to be processed 12, one of the first and second gases may be a carrier gas, and the other may be an etching gas. This is because the densities of the etching gas and the carrier gas can be precisely controlled in the chamber. If the second gas is an etching gas, the amount of the gas to be supplied for etching treatment of the surface of the object to be processed 12 under reduced pressure may be decreased. If the second gas is a carrier gas (a gas which does not react with the surface of the object to be processed), deposits accumulated on the surface of the object to be processed during etching treatment can be easily blown away and thus removed, and thus the amount of gas required for the cleaning treatment of the corresponding surface can be reduced.

In the plasma etching apparatus in accordance with the present invention, the gas supply tube may be formed of a pipe extending substantially parallel to the surface of the object to be processed. In this case, the first and second gas supply openings are positioned above the object to be processed, and are opened laterally. Therefore, it is preferable that wall surfaces of shapes capable of changing the respective directions of the flows of the gases along the direction substantially perpendicular to the surface of the object to be processed be disposed in contact with the gas supply ports. For example, it is preferable that the gas injection openings having the wall surface be formed by forming a notch portion, a recess or the like in the side surface of a pipe and opening the gas supply port toward the wall surface forming the notch portion, the recess or the like.

Furthermore, in this case, it is preferable that the first gas supply opening be disposed above the second gas supply opening in the gas injection openings. This is because the dispersion of the first gas injected from the gas injection openings can become greater than the dispersion of the second gas, so that the second gas can be easily injected to the space the pressure of which has been increased by the injecting of the first gas.

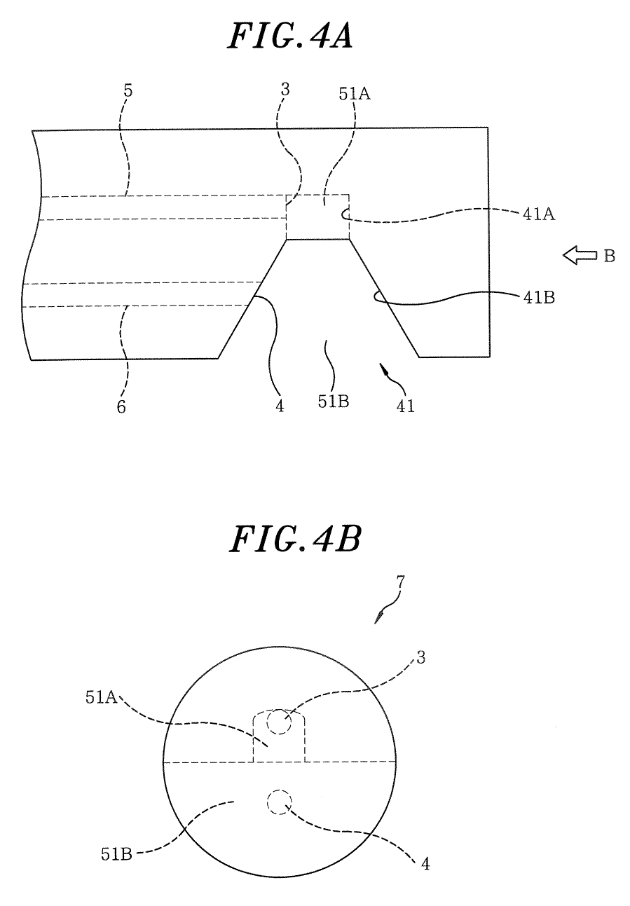

FIG. 4A is a view describing an example of the structure of the gas injection opening in the gas supply tube, and indicates the gas supply passage and a recess in dashed lines. FIG. 4B is a view showing the gas supply tube when viewed from direction B of FIG. 4A. In the drawings starting from FIG. 4B, the inner structure of the gas supply tube is represented by dashed lines.

The gas supply tube 7 is a cylinder in which the first and second supply paths 5 and 6 run through the interior thereof along the longitudinal direction thereof. The gas injection opening 41 opened toward the surface of the object to be processed (not shown) disposed on the lower side of FIG. 4A is formed at the tip of the gas supply tube 7. The gas injection opening 41 includes a notch portion 51B and a recess 51A formed above the notch portion 51B. The notch portion 51B is configured such that the second gas supply opening 4 is opened into the inside of the notch portion 51B and such that the side surface 41B faces the gas supply port 4. The recess 51A is configured such that the first supply opening 3 is opened into the inside of the recess 51A and the wall surface 41A faces the gas supply port 3.

The wall surface 41A is provided in the recess 51A, and has a shape that changes the flow of the laterally injected first gas into a flow along a downward direction. In particular, it has a planar shape that is perpendicular to the lengthwise direction of the supply paths 5 and 6, that is, a planar shape that is perpendicular to the surface of the object to be processed. The wall surface 41B has a shape that not only changes the direction of the flow of the second gas in the notch portion 51B, but also laterally spreads the first gas whose direction of the flow has been changed outwardly toward the space into which the second gas is injected, to thereby inject the first gas from the gas injection opening 41 thereto. In particular, it has a planar shape that is inclined to widen its opening from the side of the second gas supply opening to the front end of the gas supply tube toward the opening side of the gas injection opening 41 and comes into contact with the end of the wall surface 41A.

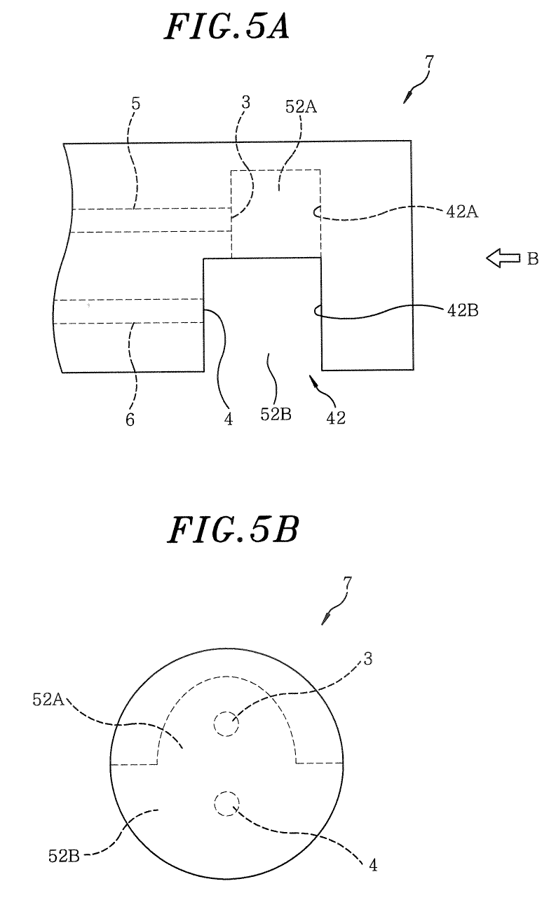

FIGS. 5A to 9A are views illustrating other examples of the structure in the vicinity of the gas injection opening in the gas supply tube 7. FIGS. 5B to 9B are views showing the gas supply tube when viewed in the direction B of FIGS. 5A to 9A.

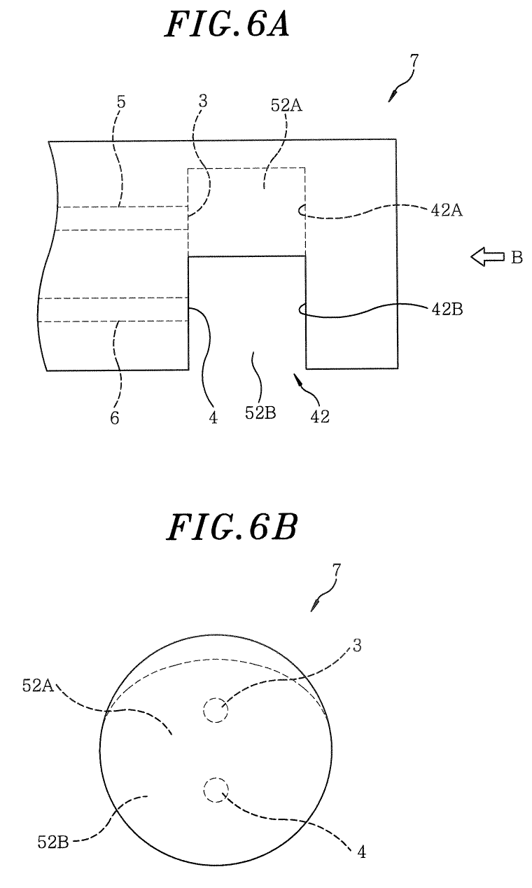

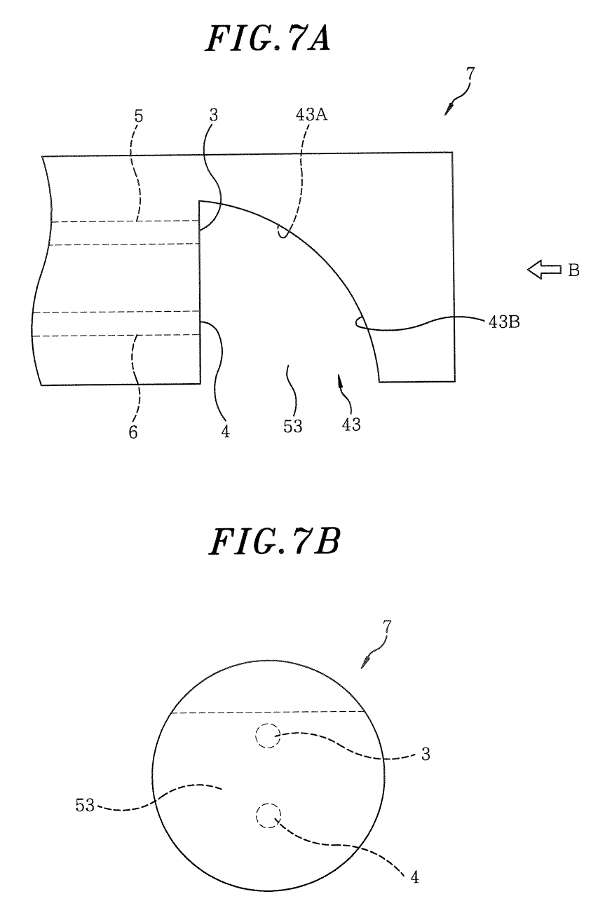

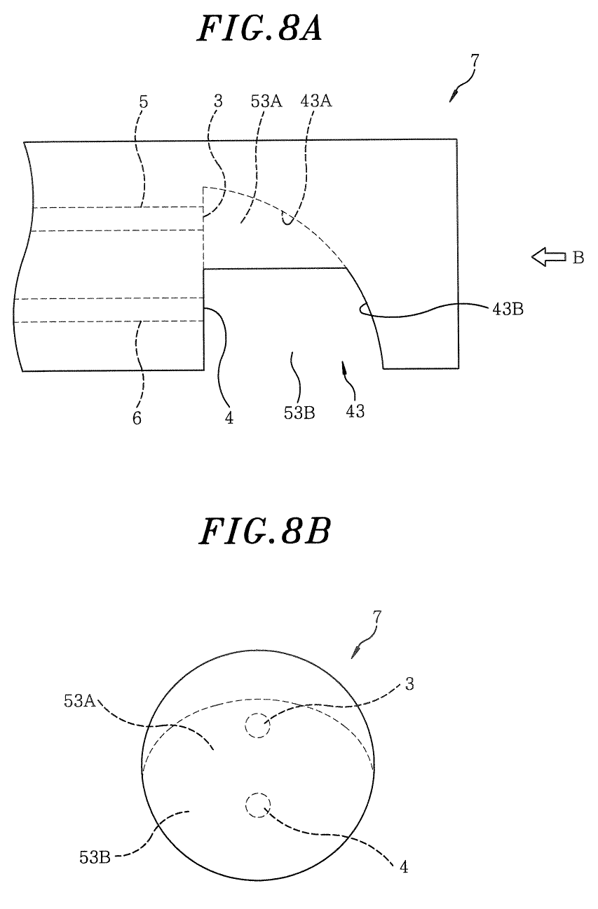

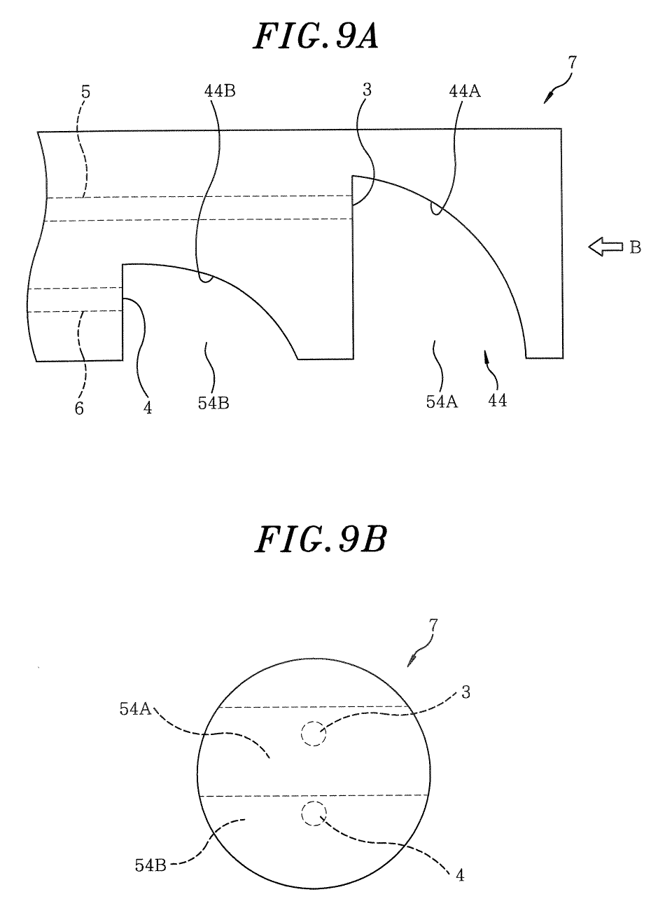

The structure of the injection opening in the gas supply tube 7 is not particularly restricted, as long as the first gas supply opening 3 is disposed above the second gas supply opening 4 and has a wall surface against which the gases injected through the gas supply ports are made to collide such that the corresponding wall surface changes the direction of the flow of the gas transversely injected through the gas supply opening toward the lower side in the interior of the gas injection openings. For example, as shown in FIGS. 5 and 6, the gas injection opening 42 may include a notch portion 52B and a recess 52A, formed above the notch portion 52B, that are formed such that the side surfaces 42A and 42B facing the first and second gas supply openings 3 and 4 are planar shapes perpendicular to the lengthwise direction of the first and second supply paths 5 and 6, respectively. Furthermore, for example, as shown in FIGS. 7 and 8, the gas injection openings 43 may include a notch portion 53, or a notch portion 53B and a recess 53A, formed above the notch portion 53B, that are formed such that the wall surfaces 43A and 43B facing the gas supply ports 3 and 4, respectively, have concave surface shapes that are inclined to widen its opening from the side facing the gas supply port to the tip end of the gas supply tube toward the opening side of the gas injection openings 43. Furthermore, in the gas supply tube 7, the gas injection openings may include a plurality of openings. For example, as shown in FIG. 9, a gas injection opening 44 formed by having the notch portions 54A and 54B to provided so as to be closely located to each other may be formed in the side surface of the cylinder. In this case, the notch portion 54A may be formed such that the first gas supply opening 3 is opened toward the interior thereof and the notch portion 54B may be formed such that the second gas supply opening 4 is opened toward the interior thereof. The side surfaces 44A and 44B respectively facing the first and second gas supply openings 3 and 4 have concave surface shapes, which are inclined to widen its opening from the side facing the side of the gas supply port and the tip of the gas supply tube toward the opening side of the gas injection openings 44 in order to easily inject the second gas to a space the pressure of which is increased by the injection of the first gas. Furthermore, the curvature of the wall surface 44A is set to a value larger than the curvature of the wall surface 45B.

The plasma etching apparatus of the present invention may be used for plasma treatment, other than plasma etching, by properly setting the types of gases supplied from the gas supply unit. For example, the formation of a film by using plasma CVD may be performed by using an organic silicon compound gas or an organic metal compound gas as a supplied gas.

As described above, the present invention has enormous usefulness in the technical field of manufacturing semiconductors by providing a plasma etching apparatus that is capable of reducing the amount of supplied gas required for the surface treatment of an object to be processed.

While the invention has been shown and described with respect to the embodiment, it will be understood by those skilled in the art that various changes and modifications may be made without departing from the scope of the invention as defined in the following claims.

What is claimed is:

1. A plasma etching apparatus for plasma-etching on an object to be processed, comprising:
a chamber;
a support disposed in the chamber to hold the object to be processed;
a gas supply unit for supplying gases into the chamber;
a plasma generating unit for generating a plasma of the gases supplied into the chamber; and
a gas exhaust unit for pumping the inside of the chamber to reduce an inner pressure of the chamber;
wherein the gas supply unit includes a gas supply tube having a gas injection opening for injecting the gases toward the object to be processed held on the support, the gas injection opening having one or more first gas supply openings for injecting a first gas and a second gas supply opening for injecting a second gas for processing the object to be processed; and
wherein the gas supply unit supplies the second gas to a surface of the object to be processed by injecting first the first gas toward the object to be processed from said one or more first gas supply openings into the chamber whose pressure has been reduced by the gas exhaust unit, and then injecting the second gas toward the object to be processed from the second gas supply opening via a space whose pressure has been increased by the first gas.

2. The plasma etching apparatus of claim 1, wherein the gas exhaust unit reduces the inner pressure of the chamber down to a range from about 133.3 mPa to 13.33 Pa.

3. The plasma etching apparatus of claim 1, wherein the gas supply tube has a first tube portion and a second tube portion into which the gases are introduced from the first tube portion, the first tube portion being introduced into the chamber toward a space of the chamber above the object to be processed by being extended substantially parallel to a surface of the object to be processed while the second tube portion having the gas injection opening at a tip thereof and extending substantially vertically to the surface of the object to be processed.

4. The plasma etching apparatus of claim 3, wherein a length of the second tube portion ranges from about 5 mm to 150 mm.

5. The plasma etching apparatus of claim 1, wherein the gas injection opening has one first gas supply opening and the first gas supply opening has a ring shape surrounding the second gas supply opening.

6. The plasma etching apparatus of claim 1, wherein the gas injection opening has more than one first gas supply opening disposed around the second gas supply opening.

7. The plasma etching apparatus of claim 1, wherein the gas supply tube has a wall surface causing the first and the second gas injected through the first gas supply openings and the second gas supply opening to collide therewith, and changes flow directions of the first and the second gas by causing the first and second gases to collide with the wall surface, thereby injecting the first and the second gas toward the object to be processed.

8. The plasma etching apparatus of claim 1, wherein the gas supply unit includes a gas supply control mechanism controlling supply of the first and the second gas, the gas supply control mechanism starting to inject the second gas while the first gas is being injected.

9. The plasma etching apparatus of claim 1, wherein a distance between the gas injection opening and the support ranges from about 10 mm to 150 mm.

10. The plasma etching apparatus of claim 1, wherein the second gas is a gas for etching the object to be processed.

11. The plasma etching apparatus of claim 1, wherein the second gas is a gas for cleaning the surface of the object to be processed not reacting with the surface of the object to be processed.

12. The plasma etching apparatus of claim 1, wherein the plasma generating unit includes a radial line slot antenna provided with an antenna body provided with an outer surface forming a surface for radiating a microwave and disposed outside the chamber to face the object to be processed; a wave retarding plate formed of a dielectric member and disposed to cover the outer surface; and a slot plate having a plurality of slots to cover the dielectric member.
